(19) United States
(12) Patent Application Publication
(10) Pub. No.: US 2026/0292998 A1
(43) Pub. Date: Sep. 24, 2026

(54) CONNECTION CARRIER, METHOD FOR PRODUCING A SOLDER JOINT AND DEVICE

(71) Applicant: ams-OSRAM International GmbH, Regensburg (DE)

(72) Inventors: Sebastian Wittmann, Ergoldsbach (DE); Markus Kirsch, Brunn (DE)

(21) Appl. No.: 19/475,393

(22) PCT Filed: May 29, 2024
(86) PCT No.: PCT/EP2024/064756

§ 371 Date: Oct. 14, 2025

(30) Foreign Application Priority Data
Jun. 20, 2023 (DE) 102023116055.9

(51) Int. Cl. H05K 3/341; H05K 1/02; H05K 1/181

(52) U.S. Cl. CPC H05K 3/341; H05K 1/0274; H05K 1/181; H05K 2201/10106; H05K 2201/2081

(57) ABSTRACT

In an embodiment a connection carrier includes a main body with a metallization and a solder resist layer arranged at least in places on the metallization, wherein the solder resist layer has a thickness of at most 5 micrometers, and wherein the main body is transparent to visible light, IR radiation and/or UV radiation.

### CROSS-REFERENCE TO RELATED APPLICATIONS

This patent application is a national phase filing under section 371 of PCT/EP2024/064756, filed May 29, 2024, which claims the priority of German patent application no. 102023116055.9, filed Jun. 20, 2023, each of which is incorporated herein by reference in its entirety.

### TECHNICAL FIELD

A connection carrier, a method for producing a solder joint, and a device are specified.

### SUMMARY

Embodiments provide a connection carrier that enables an efficient solder joint to be produced with an electronic component. Further embodiments provide a simple and efficient method for producing a solder joint and a device.

According to at least one embodiment, the connection carrier comprises a main body with a metallization. The main body serves in particular for the mechanical stabilization of components arranged therein or thereon. The main body is, for example, rigid or mechanically flexible. In particular, the main body is impervious to visible light. Alternatively, the main body may be transparent to visible light, IR radiation and/or UV radiation. For example, the main body then has a transparency of at least 90% or at least 95% for visible light, IR radiation and/or UV radiation incident thereon. For example, the main body comprises a plastic or is formed thereof.

A transparent main body has the advantage that the connection carrier and thus also a device comprising the connection carrier appears transparent to a human observer. This allows the connection carrier to be used, for example, for backlighting applications, for example in displays.

In particular, the metallization is in the form of conductor tracks. The metallization is arranged on the main body, for example. The metallization can be used for electrical contacting of components arranged on the connection carrier.

According to at least one embodiment of the connection carrier, a solder resist layer is applied at least in places to the metallization. In particular, the solder resist layer completely covers the metallization in places where the metallization is not covered by material of the main body. For example, the solder resist layer is in direct contact with the metallization. In particular, the solder resist layer is electrically insulating.

The solder resist layer is designed in particular to prevent a liquefied solder material from flowing. In other words, the solder resist layer has a dewetting effect for liquefied solder material. In particular, the liquefied solder material does not spread on the solder resist layer. Here and in the following, spreading refers to the spreading of a liquid, such as the liquefied solder material, on a surface in the form of a flat film. During spreading, a macroscopic contact angle of 0° can in particular be observed.

For example, the solder resist layer can be structured. In other words, the solder resist layer can be applied to the metallization in a structured manner or can be structured, in particular by photostructuring. For example, the solder resist layer comprises an organic material such as a spray lacquer. Alternatively, the solder resist layer can be formed with an inorganic material, for example a metal nitride.

According to at least one embodiment of the connection carrier, the solder resist layer comprises a thickness of at most 5 micrometers, in particular of at most 3 micrometers. The solder resist layer may comprise a thickness of at least 0.2 micrometers or of at least one micrometer. The thickness is determined, for example, in a vertical direction that runs perpendicular to a main extension direction of the connection carrier.

According to at least one embodiment, the connection carrier comprises the main body with the metallization, wherein the solder resist layer is applied at least in places on the metallization and the solder resist layer comprises a thickness of at most 5 micrometers. In particular, the connection carrier is a printed circuit board (PCB).

In other connection carriers, the solder resist layer may, for example, comprise a thickness in the region of 30 micrometers to 40 micrometers. As a result, solder paste that is only to be applied to small regions with a maximum extension of 100 micrometers, in particular a maximum of 50 micrometers, for example a maximum of 20 micrometers, may no longer adhere to the connection carrier.

Presently, the solder resist layer has a significantly lower thickness than in the other connection carriers. Therefore, the solder paste adheres to the connection carrier even when applied to the small regions. This has the advantage that components with dimensions in the micrometer range can also be effectively connected to the connection carrier.

As an alternative to using a solder resist layer, a laser stop is also used in other connection carriers. With a laser stop, a gold layer with good wettability is partially removed using a laser and an underlying nickel layer is exposed. The nickel layer oxidizes, for example due to environmental influences, and has a dewetting effect. The solder material therefore flows less on the nickel layer, allowing the solder joint to be produced in the small regions. However, the use of the laser stop can damage the main body and result in aging problems. The use of the solder resist layer described here advantageously avoids damage to the main body and the resulting aging problems.

According to at least one embodiment of the connection carrier, the solder resist layer comprises or consists of copper(I) nitride (Cu₃N). Copper(I) nitride advantageously allows a thin solder resist layer to be formed. In addition, copper(I) nitride is particularly characterized in that it has dewetting effect on liquefied solder material. The copper(I) nitride can also serve as corrosion protection for the underlying metallization.

According to at least one embodiment of the connection carrier, the solder resist layer comprises a thickness of at most 100 nanometers, in particular at most 50 nanometers, for example in the region between and including 15 nanometers and 30 nanometers. In particular, such a thickness is achieved with a metal nitride, for example copper(I) nitride, as the material for the solder resist layer.

According to at least one embodiment of the connection carrier, the metallization comprises or consists of copper. A metallization made of or with copper can be easily applied to the main body. For example, the metallization comprising or consisting of copper is applied to the main body by printing.

According to at least one embodiment of the connection carrier, the metallization comprises a layer of nickel and/or a layer of gold. In particular, the metallization comprises a layer stack of the following materials: copper, nickel, gold. For example, the materials are arranged in the order indicated, with the copper in direct contact with the main body of the connection carrier. Advantageously, a solder joint can be efficiently produced with metallization comprising a layer of nickel and/or a layer of gold.

According to at least one embodiment of the connection carrier, the metallization comprises at least two regions. The two regions are in particular electrically isolated from each other by a recess. This advantageously allows an electrical component to be electrically connected via the two regions of the metallization. For example, the two regions of the metallization are two electrically isolated conductor tracks.

According to at least one embodiment of the connection carrier, the solder resist layer in the recess is in direct contact with the main body. In particular, the solder resist layer is applied to the main body between the at least two regions of the metallization. For example, the solder resist layer completely covers one side of the connection carrier. In other words, in this embodiment, both the metallization and regions of the main body that are not covered by the metallization are covered by the solder resist layer.

According to at least one embodiment of the connection carrier, the metallization is free of the solder resist layer on a side facing away from the main body in the region of the recess. In other words, the solder resist layer does not completely cover the metallization. For example, the metallization is free of the solder resist layer in regions that are intended for connecting an electrical component. Advantageously, a solder joint with a defined size can be produced at the regions of the metallization that are free of the solder resist layer because the solder resist layer prevents, in particular, spreading of liquefied solder material.

A method for producing a solder joint is also described. In particular, the connection carrier described here is suitable for use in the method for producing a solder joint. Embodiments, features, and advantages described in connection with the connection carrier therefore also apply to the method and vice versa.

According to at least one embodiment of the method, a connection carrier comprising a main body with a metallization is provided. A solder resist layer is applied at least in places on the metallization. The solder resist layer comprises a thickness of at most 5 micrometers.

According to at least one embodiment of the method, a solder paste is applied next to or on the solder resist layer. In particular, the solder paste is applied to regions of the connection carrier which are subsequently intended to serve for contacting and/or fastening an electrical component. For example, the solder paste comprises a solder material.

According to at least one embodiment of the method, the solder paste is at least partially melted. In particular, the solder material in the solder paste is melted. It is also possible that other components of the solder paste are melted.

According to at least one embodiment of the method, an electronic component is applied. In particular, the electronic component is applied before or after the solder joint is at least partially melted. The electronic component is applied, for example, so that it is in direct contact with the solder paste or with the at least partially melted solder paste.

According to at least one embodiment of the method, the solder joint is formed. In particular, the solder joint is formed between the connection carrier and the electronic component by the solder material solidifying. The solder joint enables, for example, a material-locking, electrically conductive connection between the connection carrier and the electronic component.

According to at least one embodiment, the method for producing a solder joint comprises the following steps:
providing the connection carrier comprising the main body with the metallization, wherein the solder resist layer is applied at least in places on the metallization and the solder resist layer comprises a thickness of at most 5 micrometers,
applying the solder paste next to or on the solder resist layer,
applying the electronic component,
at least partially melting the solder paste, and
forming the solder joint.

In particular, the steps are carried out in the order specified. However, it is also possible to swap the steps of applying the electronic component and at least partially melting the solder paste.

Advantageously, during the method, the solder material of the solder paste is prevented from flowing or spreading over the connection carrier by the solder resist layer. This allows a solder joint with a defined size to be produced. Therefore, the solder joint produced can advantageously have a greater thickness than solder joints produced on another connection carrier. For example, the solder joint produced by the method described here is twice as high as a solder joint on another connection carrier. A thicker solder joint is, for example, more reliable.

According to at least one embodiment of the method, a stencil, for example made of metal, is used when applying the solder paste. In particular, the solder paste is printed on with the aid of the stencil. The stencil advantageously allows the solder paste to be applied selectively to predetermined regions. Since the solder resist layer has a thickness of at most 5 micrometers, it is possible to apply the solder paste even to small regions, i.e., regions with an extension in the micrometer range.

According to at least one embodiment of the method, the solder paste comprises a solder material formed with at least one element from the group Sn, Pb, Bi, Sb, Ag, Cu, and Au. In particular, the solder material is selected from the following group: Sn, SnAgCu, SnAu, SnAg, SnSb, SnPb, SnBi, and mixtures thereof.

According to at least one embodiment of the method, the solder paste comprises a flux. The flux leads, in particular via its constituents, to cleaning and/or activation of a surface to be soldered. Presently, the flux may have a reducing effect. In particular, the flux comprises a material selected from the following group: succinic acid, formic acid, hydrochloric acid, adipic acid, phosphoric acid, salts and mixtures thereof. Zinc chloride and/or ammonium chloride are used as salts, for example.

According to at least one embodiment of the method, the solder resist layer comprises or consists of copper(I) nitride. The solder paste further comprises a flux. During melting of the solder paste, the copper(I) nitride is reduced. In particular, elemental copper is formed. Advantageously, it is thus possible to apply the solder resist layer over the entire surface of the metallization. A structuring of the solder resist layer is therefore in particular not necessary. The reduction of the copper(I) nitride is made possible, for example, by the presence of the flux in the solder paste. In particular, succinic acid enables the reduction of copper(I) nitride to elemental copper.

According to at least one embodiment of the method, the metallization comprises at least two regions which are separated from each other by a recess. In particular, the solder paste is applied in the region of the recess. The solder paste can fill the recess at least partially. Alternatively, the solder paste can be applied in such a way that the recess remains at least partially free of solder paste and the solder paste is applied only to those regions of the two regions of the metallization that are adjacent to the recess.

According to at least one embodiment of the method, the solder paste comprises an epoxy resin and/or a silicone resin. The epoxy resin and/or the silicone resin remain in particular in the solder joint. This advantageously allows a better mechanical connection of the electronic component, which is to be coupled to the connection carrier by means of the solder joint, to the connection carrier. In other words, the epoxy resin and/or the silicone resin serve as an additional adhesive in the solder joint. For example, the epoxy resin and/or the silicone resin are cured in a separate step after the solder joint has been produced. Alternatively, the epoxy resin and/or the silicone resin may be cured during the production of the solder joint, for example during cooling of the molten solder material.

A device is also described. In particular, the device comprises the connection carrier described here. Furthermore, a solder joint can be produced in the device using the method described here. Embodiments, features, and advantages described in connection with the method and the connection carrier therefore also apply to the device and vice versa.

According to at least one embodiment, the device comprises a connection carrier described herein, an electronic component, and a solder joint between the connection carrier and the electronic component. In particular, the solder joint is arranged between the metallization of the connection carrier and the electronic component.

In particular, the electronic component is an optoelectronic semiconductor chip that is designed to generate or detect electromagnetic radiation. The optoelectronic semiconductor chip is, for example, a sapphire flip chip.

Advantageously, the device can be used in rear lights, backlights for displays or in a video wall, in particular due to the transparent main body of the connection carrier.

According to at least one embodiment of the device, the electronic component comprises or is a micro-LED. LED is the abbreviation for light-emitting diode. In particular, the micro-LED is designed to emit electromagnetic radiation.

Micro-LEDs can have a width, a length, a thickness, and/or a diameter less than or equal to 100 micrometers, in particular less than or equal to 70 micrometers, for example less than or equal to 50 micrometers. In particular, micro-LEDs, for example rectangular micro-LEDs, comprise an edge length, in particular in a plan view of the layers of the layer stack, of a luminous area less than or equal to 70 micrometers, for example less than or equal to 50 micrometers. A micro-LED is, for example, a light-emitting diode in which a growth substrate has been removed so that the thickness of the micro-LED is, for example, in the region of between and including 1.5 micrometers and 10 micrometers.

For example, the micro-LED is provided on a wafer with releasable holding structures. The micro-LED can be detached from the wafer without damage.

Micro LEDs are mainly used in displays. The micro-LEDs form pixels or subpixels and emit light in a defined color. Due to their small pixel size and high density at small distances, micro-LEDs are suitable for small monolithic displays for augmented reality applications, in particular data glasses. In addition, further applications are being developed, in particular for use in data communication or for pixelated lighting applications.

According to at least one embodiment of the component, a conversion region forms a boundary region between the solder joint and the solder resist layer. In other words, the conversion region is arranged between the solder joint and the solder resist layer. In particular, the conversion region at least partially, for example completely, encloses the solder joint in plan view. For example, the conversion region is formed during the melting of the solder paste.

According to at least one embodiment of the component, the conversion region comprises a reduction product of a material of the solder resist layer. In particular, the reduction product is formed during the melting of the solder paste. If the solder resist layer comprises copper(I) nitride or is formed therefrom, the reduction product is, for example, elemental copper.

### BRIEF DESCRIPTION OF THE DRAWINGS

Further advantageous embodiments, configurations, and further developments of the connection carrier, the method for producing a solder joint and the device result from the following exemplary embodiments shown in conjunction with the figures.

FIGS. 1 to 3 each show schematic cross-sectional views of a connection carrier according to an exemplary embodiment;

FIGS. 4 to 8 show schematic cross-sectional views of steps of a method for producing a solder joint according to an exemplary embodiment;

FIGS. 9 to 13 show schematic cross-sectional views of steps of a method for producing a solder joint according to a further exemplary embodiment; and

FIGS. 14 and 15 show schematic plan views of steps of a method for producing a solder joint according to an exemplary embodiment.

Identical, similar, or functionally equivalent elements are designated by the same reference signs in the figures. The figures and the relative sizes of the elements shown in the figures are not to be considered to be to scale. Rather, individual elements, in particular layer thicknesses, may be exaggerated for clarity and/or better understanding.

### DETAILED DESCRIPTION OF ILLUSTRATIVE EMBODIMENTS

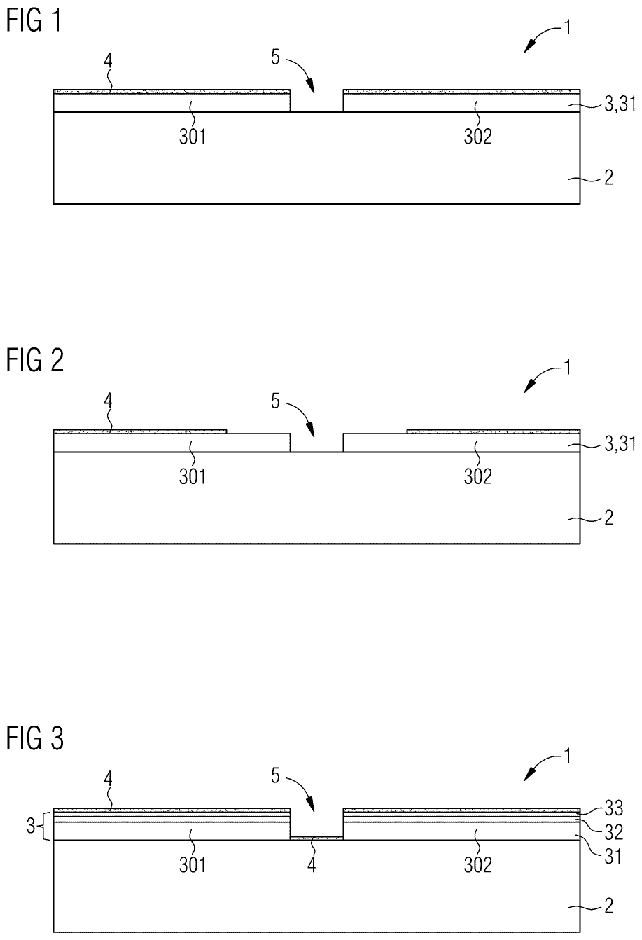

The exemplary embodiment of a connection carrier 1 according to FIG. 1 comprises a main body 2. The main body 2 is transparent to visible light, IR radiation, and/or UV radiation and comprises a plastic. A metallization 3 is applied to the main body 2. The metallization comprises a copper layer 31. Presently, the metallization 3 is in direct contact with the main body 2.

The metallization 3 comprises a first region 301 and a second region 302. The first region 301 and the second region 302 are electrically isolated from each other by a recess 5. In other words, in the region of the recess 5, the main body 2 is free of the metallization 3.

In the present exemplary embodiment, a solder resist layer 4 is arranged on the metallization 3. The solder resist layer 4 completely covers the metallization 3. The solder resist layer 4 has a thickness of approximately 30 nanometers and is in direct contact with the metallization 3. The solder resist layer 4 comprises copper(I) nitride or consists thereof. In the recess 5, the main body 2 is free of the solder resist layer 4.

Compared to the exemplary embodiment of the connection carrier 1 in FIG. 1, the connection carrier 1 in FIG. 2 comprises a solder resist layer 4 which does not completely cover the metallization 3. Otherwise, the connection carrier 1 in FIG. 2 is constructed analogously to that in FIG. 1.

The solder resist layer 4 of the connection carrier 2 shown in FIG. 2 does not completely cover the metallization 3. Presently, the metallization 3 is free of the solder resist layer 4 in the region of the recess 5. The solder resist layer 4 is therefore structured.

The structured solder resist layer 4 of FIG. 2 is produced, for example, by covering the regions of the metallization 3 which are to be free of the solder resist layer 4 with a photoresist. The solder resist layer 4 is then applied. After removing the photoresist, the regions that were covered with the photoresist are then free of the solder resist layer 4.

In FIG. 3 a further exemplary embodiment of a connection carrier 1 is shown. The connection carrier 1 presently comprises a main body 2 on which a metallization 3 is arranged. The metallization comprises a copper layer 31, a nickel layer 32, and a gold layer 33, which are arranged one above the other in this order. The copper layer 31 is in direct contact with the main body 2. The metallization 3 comprises a first region 301 and a second region 302, which are separated from each other by a recess 5.

A solder resist layer 4, which is in direct contact with the gold layer 33 of the metallization 3, is arranged on a side of the metallization 3 facing away from the main body 2. The solder resist layer 4 has a thickness of at most 5 micrometers and is formed from a non-conductive material. The solder resist layer 4 is also arranged in the recess 5. At the same time, the solder resist layer 4 covers the main body 2 and is in direct contact with the main body 2.

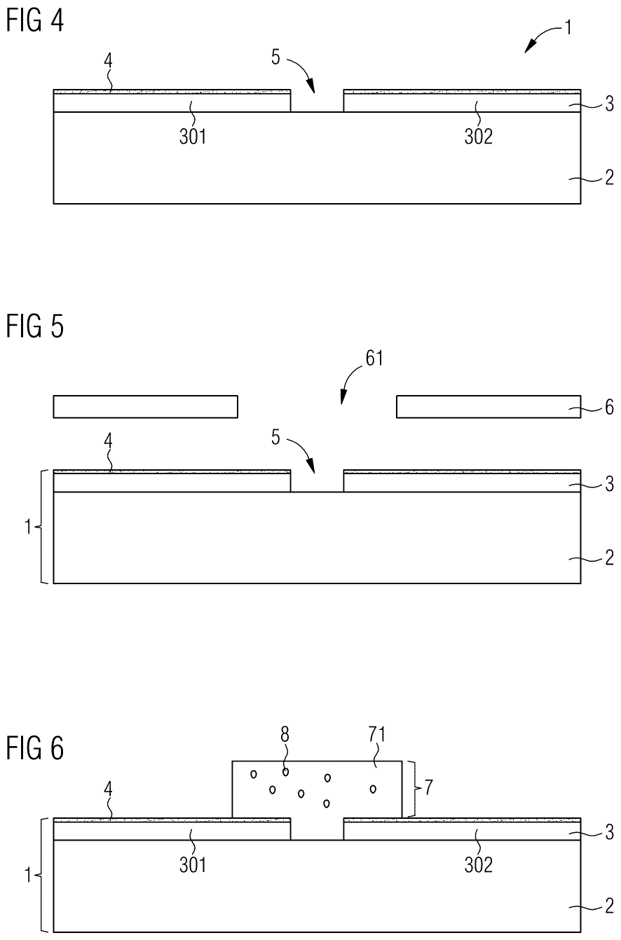

FIGS. 4 to 8 show a method for producing a solder joint 12. First, a connection carrier 1 is provided, as shown in FIG. 4. The connection carrier 1 shown in FIG. 4 has the same structure as already described in connection with FIG. 1.

In FIG. 5 it is shown how a stencil 6 is positioned so that an opening 61 of the stencil 6 is arranged in the region of the recess 5. The stencil 6 is presently formed from a metal.

A solder paste 7 is applied in the region of the recess 5 with the aid of the stencil 6. Since the solder resist layer 4 on the metallization 3 has a thickness of at most 5 micrometers, the distance between the stencil 6 and the connection carrier can be kept as small as possible. Therefore, the solder paste 7 can be applied effectively even to small regions.

As shown in FIG. 6, the solder paste 7 is applied so that the first region 301 and the second region 302 of the metallization 3 are covered by the solder paste 7. The recess 5 between the first region 301 and the second region 302 is also filled with the solder paste. The solder paste 7 presently comprises a solder material 71 and a flux 8. The solder material comprises, for example, SnBi, which is characterized by a low melting point. SnBi can therefore be used to connect temperature-sensitive electronic components 11 to the connection carrier 1.

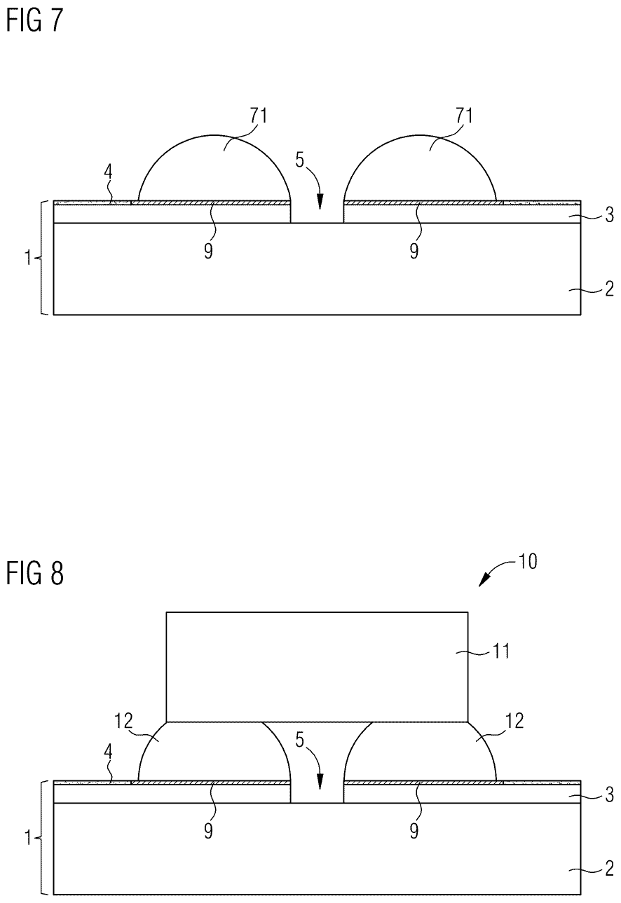

The solder paste 7 is at least partially melted. At the same time, the solder material 71 liquefies. As shown in FIG. 7, the applied solder paste 7 then separates in such a way that two separate regions with the solder material 71 are formed on the first region 301 and on the second region 302. In other words, the solder material 71 withdraws from the recess 5. A short circuit between the first region 301 of the metallization 3 and the second region 302 is prevented.

The presence of the flux 8 in the solder paste 7 causes a reduction of the solder resist layer 4, so that a conversion region 9 is formed. The conversion region 9 comprises the reduction product of the solder resist layer 4. Since the solder resist layer 4 is formed with copper(I) nitride, the conversion region 9 comprises elemental copper as a reduction product. The conversion region 9 is presently arranged between the solder material 71 and the metallization 3. Due to the different properties of the solder resist layer 4 and the conversion region 9, the solder material 71 can only flow on the conversion region 9, but not on the solder resist layer 4. This limits the expansion of the molten solder material 71.

The size of the conversion region 9 is determined by the content of the flux 8 in the solder paste 7. Thus, the composition of the solder paste 7 can advantageously be used to Docket precisely define the extent to which the molten solder material 71 spreads on the metallization 3. Presently, as seen in plan view, a margin is formed at least partially around the solder material 71 by the conversion region 9.

After the solder paste 7 is melted, an electronic component 11 is applied. The solder material 71 from the solder paste 7 solidifies and forms a solder joint 12 between the electronic component 11 and the connection carrier 1. The solder joint 12 is formed with the solder material 71.

Alternatively, it is possible that the electronic component 11 is first applied to the solder paste 7 and then the solder joint 12 is formed by melting and solidifying the solder material 71.

The device 10 produced in this way is shown in FIG. 8. The device 8 comprises a connection carrier 1 and an electronic component 11. The connection carrier 1 and the electronic component 11 are connected to each other via a solder joint 12. The solder joint 12 comprises a solder material 71. Presently, the solder material 71 comprises SnBi. The electronic component 11 is a micro-LED that emits visible light.

The connection carrier 1 comprises a main body 2 formed from a transparent plastic. A metallization 3 is arranged on the connection carrier 1. Presently, the metallization 3 comprises a copper layer 31 which is in direct contact with the main body 2. A solder resist layer 4 is arranged in places on the metallization 3. The solder resist layer 4 covers the metallization 3 on the side facing away from the main body 2. The solder resist layer 4 is formed with copper(I) nitride and also serves as corrosion protection for the metallization 3.

The metallization 3 comprises a first region 301 and a second region 302. The first region 301 and the second region 302 are electrically isolated from each other by a recess 5. The electronic component 11 is in electrical contact with the first region 301 and the second region 302 via the solder joint 12. At the same time, a solder joint 12 is arranged on both the first region 301 and the second region 302.

A conversion region 9 is arranged between the solder joint 12 and the metallization 3. The conversion region 9 comprises copper. The conversion region 9 is in direct contact with the metallization 3, the solder joint 12, and the solder resist layer 4. Presently, the conversion region 9 is adjacent to the recess 5. In plan view, the conversion region 9 forms at least in places a margin around the solder joint 12. The conversion region 9 thus forms a boundary region between the solder joint 12 and the solder resist layer 4.

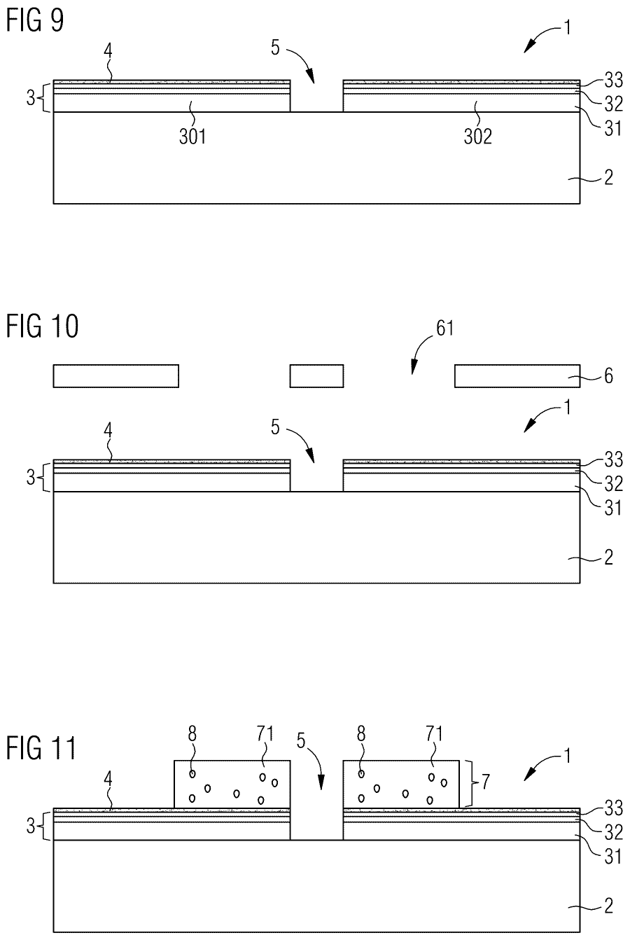

In connection with FIGS. 9 to 13, a further exemplary embodiment of the method for producing a solder joint 12 is described. First, as shown in FIG. 9, a connection carrier 1 is provided.

The connection carrier 1 presently comprises a main body 2 on which a metallization 3 is arranged. The metallization comprises a copper layer 31, a nickel layer 32, and a gold layer 33, which are arranged one above the other in this order. The copper layer 31 is in direct contact with the main body 2. The metallization 3 comprises a first region 301 and a second region 302, which are separated from each other by a recess 5.

A solder resist layer 4, which is in direct contact with the gold layer 33 of the metallization 3, is arranged on a side of the metallization 3 facing away from the main body 2. The solder resist layer 4 comprises a thickness of approximately 30 nanometers and is formed with copper(I) nitride. The solder resist layer 4 is not arranged in the recess 5.

A solder paste 7 is applied to the connection carrier 1 with the aid of a stencil 6, which presently comprises two openings 61. The arrangement of the stencil is shown in FIG. 10. The stencil 6 covers the recess 5 in the metallization 3 of the connection carrier 1. The openings 61 are arranged so that the regions of the metallization 3 adjacent to the recess 5 can be provided with the solder paste 7.

The arrangement of the solder paste 7 on the connection carrier 1 is shown in FIG. 11. The solder paste 7 does not fill the recess 5, but the solder paste 7 is adjacent to the recess 5. The solder paste 7 presently comprises a solder material 71 and a flux 8. The solder paste 7 is in direct contact with the solder resist layer 4 of the connection carrier 1.

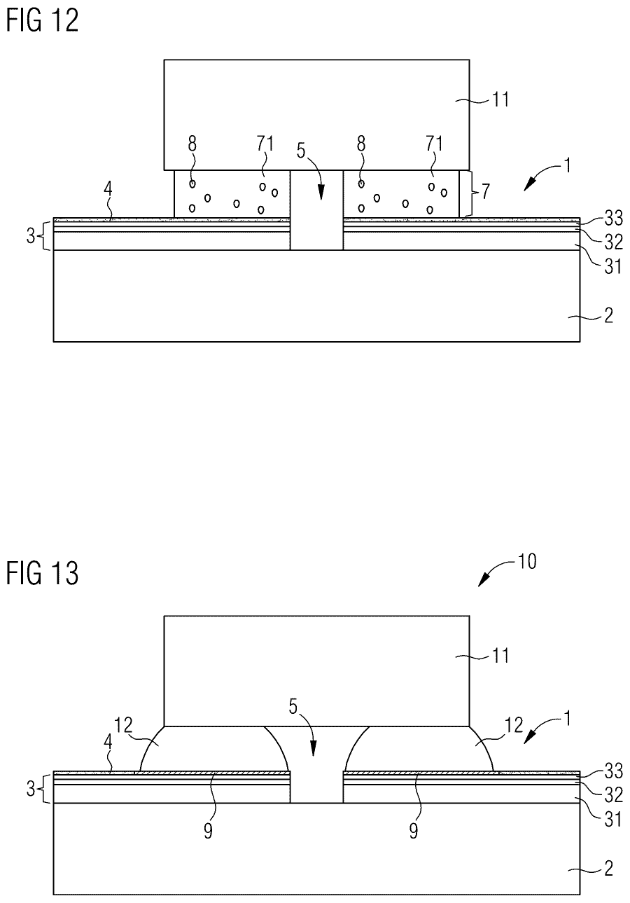

An electronic component 11, presently a micro-LED, is applied to the solder paste 7, as shown in FIG. 12.

The solder paste 7 is then melted so that the solder material 71 is at least partially liquefied. At the same time, a conversion region 9 is formed, as shown in FIG. 13. The conversion region 9 is presently located between the solder material 71 and the gold layer 33. At the same time, the conversion region 9 is in direct contact with the solder material 71 and the gold layer 33. Presently, the conversion region 9 comprises a reduction product of the solder resist layer 4, namely elemental copper. The conversion region 9 is formed during the melting of the solder paste 7 by the presence of the flux 8. The flux 8 comprises, for example, succinic acid or is succinic acid.

The solder material 71 solidifies again and a solder joint 12 forms between the electronic component 11 and the connection carrier 1.

It is also possible that the solder paste 7 additionally comprises an epoxy resin and/or a silicone resin. The epoxy resin and/or the silicone resin serve to additionally bond the electronic component 11 to the connection carrier 1. The epoxy resin and/or the silicone resin are cured together with the solder material 71 or in a separate step. The epoxy resin and/or the silicone resin is part of the solder joint 12.

The device 10 produced in this way is shown in FIG. 13. The device 10 of the exemplary embodiment of FIG. 13 is constructed analogously to the device 10 shown in FIG. 8. However, the metallization 3 presently comprises a layer stack consisting of a copper layer 31, a nickel layer 32, and a gold layer 33. Furthermore, the main body 2 of the connection carrier 1 is covered with the solder resist layer 4 in the region of the recess 5. In comparison, the recess 5 of the device 10 of FIG. 8 is free of the solder resist layer 4.

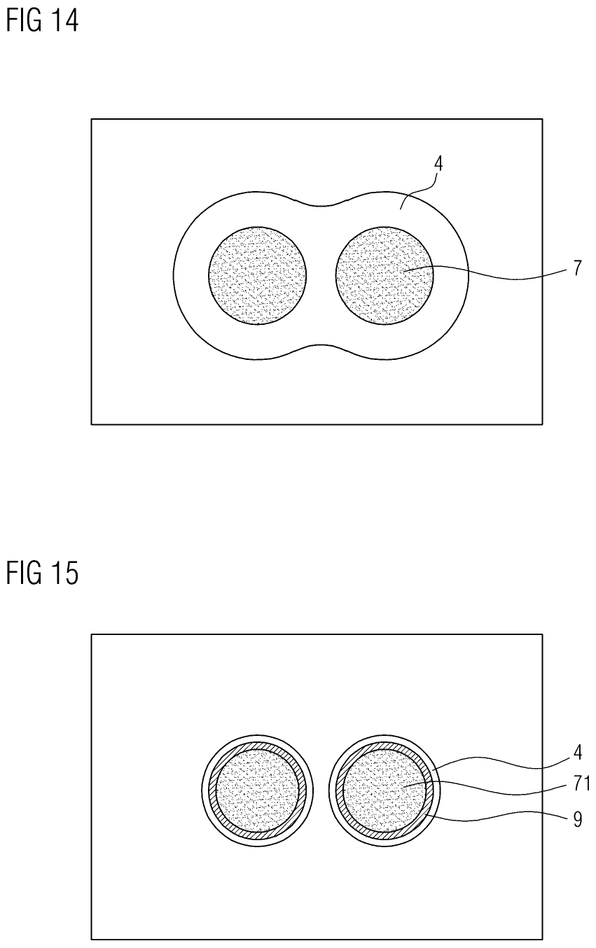

FIG. 14 shows a schematic plan view on a step in the method for producing the solder joint 12. In FIG. 14, the stage of the method after the solder paste 7 has been applied to the connection carrier 1 is shown. Presently, the solder paste 7 was applied to the connection carrier 1 in an approximately circular pattern as seen in the plan view. The solder paste 7 comprises a solder material 71, for example AuSn, and a flux 8 such as succinic acid. A solder resist layer 4 is arranged on the connection carrier 1 around the solder paste 7. The solder resist layer 4 presently comprises copper(I) nitride. The solder paste 7 was presently applied by stencil printing.

FIG. 15 shows the method stage after the solder paste 7 has been at least partially melted. The structure shown in FIG. 15 results in particular from the arrangement shown in FIG. 14. The flux 8 present in the solder paste 7 reduces the copper(I) nitride in the solder resist layer 4 at least partially to elemental copper. In this way, a conversion region 9 with the elemental copper is formed between the liquid solder material 71, later the solder joint 12, and the connection carrier 1.

Due to the solder resist layer 4, the liquid solder material 71 does not spread completely onto a surface of the connection carrier 1. This can be seen, for example, in the expansion of the solder material 71. The expansion of the solder material 71, viewed in plan view, is comparable to the expansion of the solder paste 7 shown in FIG. 14.

The spreading of the solder material 71 is additionally prevented by the formation of the conversion region 9. Presently, the conversion region 9 forms a boundary region between the solder material 71 and the solder resist layer 4. Viewed in plan view, the solder material 71 is completely enclosed by the conversion region 9. In other words, the conversion region 9 forms a margin around the solder material 71.

The features and exemplary embodiments described in connection with the figures may be combined with one another in accordance with further exemplary embodiments, even if not all combinations are explicitly described. Furthermore, the exemplary embodiments described in connection with the figures may alternatively or additionally comprise further features in accordance with the description in the general part.

The invention is not limited to the description based on the exemplary embodiments. Rather, the invention encompasses every new feature and every combination of features, including in particular every combination of features in the patent claims, even if this feature or combination is not explicitly stated in the patent claims or exemplary embodiments.

1.-17. (canceled)

18. A connection carrier comprising:
a main body with a metallization; and
a solder resist layer arranged at least in places on the metallization,
wherein the solder resist layer comprises a thickness of at most 5 micrometers, and
wherein the main body is transparent to visible light, IR radiation and/or UV radiation.

19. The connection carrier according claim 18, wherein the solder resist layer comprises or consists of copper(I) nitride.

20. The connection carrier according to claim 18, wherein the solder resist layer comprises a thickness of at most 100 nanometers.

21. The connection carrier according to claim 20, wherein the metallization comprises or consists of copper.

22. The connection carrier according to claim 18, wherein the metallization comprises a layer of nickel and/or a layer of gold.

23. The connection carrier according to claim 18, wherein the metallization comprises at least two regions, which are electrically isolated from one another by a recess.

24. The connection carrier according to claim 23, wherein the solder resist layer in the recess is in direct contact with the main body.

25. The connection carrier according to claim 23, wherein the metallization is free of the solder resist layer on a side facing away from the main body in the region of the recess.

26. The connection carrier according to claim 18, wherein the metallization on a side facing away from the main body is completely covered by the solder resist layer.

27. A device comprising
the connection carrier according to claim 18;
an electronic component; and
a solder joint between the connection carrier and the electronic component.

28. The device according to claim 27, wherein the electronic component comprises or is a micro-LED.

29. The device according to claim 27, further comprising:
a conversion region forming a boundary region between the solder joint and the solder resist layer,
wherein the conversion region comprises a reduction product of a material of the solder resist layer.

30. A method for producing a solder joint, the method comprising:
providing a connection carrier comprising a main body with a metallization, wherein a solder resist layer is applied at least in places on the metallization, wherein the solder resist layer comprises a thickness of at most 5 micrometers, and wherein the main body is transparent to visible light, IR radiation and/or UV radiation;
applying a solder paste next to or on the solder resist layer;
applying an electronic component;
at least partially melting the solder paste; and
forming the solder joint.

31. The method according to claim 30, further comprising using a stencil when applying the solder paste.

32. The method according to claim 30,
wherein the solder resist layer comprises or consists of copper(I) nitride,
wherein the solder paste comprises a flux, and
wherein the copper(I) nitride is reduced during melting of the solder paste.

33. The method according to claim 30,
wherein the metallization comprises at least two regions that are separated from each other by a recess, and
wherein the solder paste is applied in the region of the recess.

34. The method according to claim 30, wherein the solder paste comprises an epoxy resin and/or a silicone resin.
